(19) United States
(12) Patent Application Publication
(10) Pub. No.: US 2024/0088316 A1
(43) Pub. Date: Mar. 14, 2024

(54) PHOTOVOLTAIC RECEIVER FOR FREE-SPACE OPTICAL POWER BEAMING

(71) Applicant: The George Washington University, Washington, DC (US)

(72) Inventors: Raymond HOHEISEL, Washington, DC (US); David A. SCHEIMAN, Strongsville, OH (US); Justin R. LORENTZEN, Washington, DC (US); Woojun YOON, Fairfax, VA (US)

(21) Appl. No.: 17/773,486

(22) PCT Filed: Dec. 16, 2020
(86) PCT No.: PCT/US2020/065244

§ 371 Date: Apr. 29, 2022

Related U.S. Application Data
(60) Provisional application No. 62/948,632, filed on Dec. 16, 2019.

(51) Int. Cl. H01L 31/05; H01L 31/053

(52) U.S. Cl. CPC H01L 31/0504; H01L 31/053

(57) ABSTRACT

A photovoltaic receiver includes a string of photovoltaic cells that includes at least two photovoltaic cells, where the at least two photovoltaic cells are coupled to one another in series. The string of photovoltaic cells has rotational symmetry with respect to a reference point. The photovoltaic receiver further includes an energy storage element for a photovoltaic cell of the string of photovoltaic cells and being coupled to the photovoltaic cell of the string of photovoltaic cells in parallel.

### CROSS-REFERENCE TO RELATED APPLICATION

This application claims the benefit of priority of U.S. Provisional Application No. 62/948,632, filed on Dec. 16, 2019, the content of which is relied upon and incorporated herein by reference in its entirety.

### TECHNICAL FIELD

The present disclosure relates to the field of photovoltaic technology, and more particularly to a photovoltaic receiver for free-space optical power beaming.

### BACKGROUND

The optical power conversion efficiency of individual photovoltaic cells (PV) are routinely reported above 50% when exposed to a monochromatic light source, such as a laser. Free-space, optical power beaming using high power lasers require arrays of PV cells consisting of series and parallel connected strings. While this is nearly a minor detail in PV arrays using solar illumination, it is a severe complication for free-space optical (FSO) power beaming applications. Solar illumination is inherently uniform in areal intensity and temporally stable, such that each PV cell in a string will nominally generate the same current as every other cell in a string.

However, power output of PV cells under free-space optical power beaming is limited because (1) the best beam quality from a single high power laser has a Gaussian beam profile (i.e., it has a stronger intensity in the center that weakens further out); (2) atmospheric turbulence creates position displacements (beam wander); and (3) “lensing” through the atmosphere such that the intensity at any one spot on the PV array can easily be a magnitude higher or lower in intensity than what would be the average intensity without the presence of atmospheric turbulence.

The current state of the art of free-space power beaming using optical wavelengths (<2 micrometers) is limited to arrays of rectangular PV cells connected as strings in series or parallel combinations, which perform well only in short range (<500 meters), in low atmospheric turbulence, and under uniform illumination. These systems perform poorly in the presence of atmospheric turbulence and the non-uniform nature of laser light propagated over significant distances (>500 meters).

Over longer distances, only the fundamental Gaussian mode of a laser will propagate, thus an arbitrary arrangement of a string of PV cells under Gaussian illumination will see some cells with more laser light falling on them than other cells. In typical arrangements, where PV cells are connected in series, the PV cell with the least amount of light falling on it will set the current for the entire string and lower the power out of the string. It is analogous to a chain only being as strong as the weakest link. Under atmospheric turbulence the non-uniformity issue is made worse by random intensity fluctuations in both time and space.

### SUMMARY

This summary includes, in simplified form, a selection of examples that are further described in the Detailed Description. This summary is not intended to identify all key or essential features of the present disclosure.

In some examples, a photovoltaic (PV) receiver includes a string of photovoltaic cells. The string of photovoltaic cells includes at least two photovoltaic cells. The string of photovoltaic cells is coupled to one another in series. The string of photovoltaic cells has rotational symmetry with respect to a reference point. The photovoltaic receiver further includes an energy storage element for a photovoltaic cell of the string of photovoltaic cells and being coupled to the photovoltaic cell of the string of photovoltaic cells in parallel.

In certain examples, PV receivers for free-space optical power beaming may be used in applications and devices including unmanned systems, such as unmanned aerial vehicles (UAVs), unmanned surface vehicles (USVs), unmanned ground vehicles (UGVs) and unmanned undersea vehicles (UUVs), sensor networks on the ground.

### BRIEF DESCRIPTION OF THE DRAWINGS

FIGS. 1A to 1C show the spatial power density for a laser beam propagating through air with the turbulence in different numbers of time intervals.

FIG. 2 is a schematic layout of an exemplary PV receiver for free-space optical power beaming according to described examples.

FIG. 3 illustrates a diagram of another example PV receiver according to described examples.

FIG. 4 illustrates a circuit diagram of another example PV receiver according to described examples.

FIGS. 5A to 5D illustrate example current-versus-time graphs for the PV receiver of FIG. 4 according to described examples.

FIG. 6 illustrates a block diagram of an exemplary PV-receiver device 600 according to described examples.

### DETAILED DESCRIPTION

In describing the illustrative, non-limiting embodiments illustrated in the drawings, specific terminology will be resorted to for the sake of clarity. However, the disclosure is not intended to be limited to the specific terms so selected, and it is to be understood that each specific term includes all technical equivalents that operate in similar manner to accomplish a similar purpose. Several embodiments are described for illustrative purposes, it being understood that the description and claims are not limited to the illustrated embodiments and other embodiments not specifically shown in the drawings may also be within the scope of this disclosure.

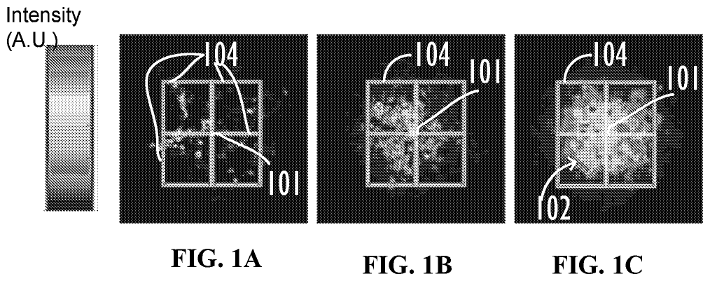

A laser beam propagating through atmospheric turbulence may experience scintillation; and the projected beam may be disrupted both spatially and temporally. FIGS. 1A, 1B, and 1C show spatial power density averaged over different numbers of time intervals for a laser beam propagating through air with high turbulence from a computer simulation of laser propagation through turbulent atmosphere, according to described examples. FIG. 1A shows the spatial power density for a laser beam propagating through air with the turbulence in a single interval of time; FIG. 1B shows the spatial power density for the laser beam propagating through air with high turbulence averaged over 10 intervals of time; and FIG. 1C shows the spatial power density for the laser beam propagating through air with high turbulence averaged over 30 intervals of time. The outline of a string of example photovoltaics (PV) cells 104 is silhouetted in FIGS. 1A to 1C, so as to show exemplary distribution of spatial power density over the string of photovoltaics (PV) cells 104. The string of PV cells 104 includes four photovoltaics (PV) cells 104, and have rotational symmetry around a center 101. Rotational symmetry may include rotational symmetry of various orders and/or circular symmetry.

In the examples of FIG. 1, the string of PV cells 104 have the rotational symmetry with an order of 4. The order of the rotational symmetry of the string of PV cells 104 is the number of times that the string of PV cells 104 appear to be the same while rotating through a full turn of 360 degrees around the center 101. The string of PV cells 104 appear to be the same, as being rotated by 90 degrees, 180 degrees, 270 degrees, and 360 degrees.

Referring to FIG. 1C, for the spatial power density for the laser beam propagating through air with high turbulence averaged over 30 intervals of time, a circularly symmetric Gaussian beam pattern 102 is beginning to emerge, and near equal amounts of energy are falling on each of the PV cells 104. Given enough time, the average energy over the beam area will have a Gaussian distribution, and evenly illuminate each cell in the string. That is, the average energy received by each cell of the four cells 104 (FIG. 1C) is same or similar.

In a long-haul free-space power beaming application, multi-mode and single mode laser beams diverge; and at long distances (e.g., a distance larger than 1 km), the only remaining mode may be a beam with a radially symmetric Gaussian profile. Free-space is the atmosphere with a gaseous envelope that surrounds the earth, extending from sea level to an altitude of several hundred kilometers. The upper lime of the atmosphere gas pressure decreases with increasing distance from the earth until it reaches the interplanetary value of 10-11 newton per square centimeters near 20,000 km. An example of the effectiveness of having rotationally symmetric (e.g., radially symmetric) PV strings under Gaussian illumination can be demonstrated by comparing two arrays, one with rotationally symmetric arrangement of cells in strings, and the other not.

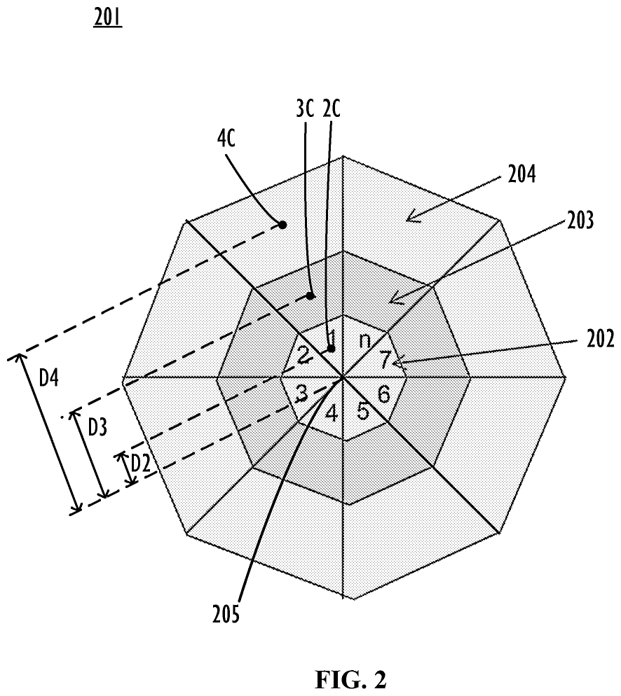

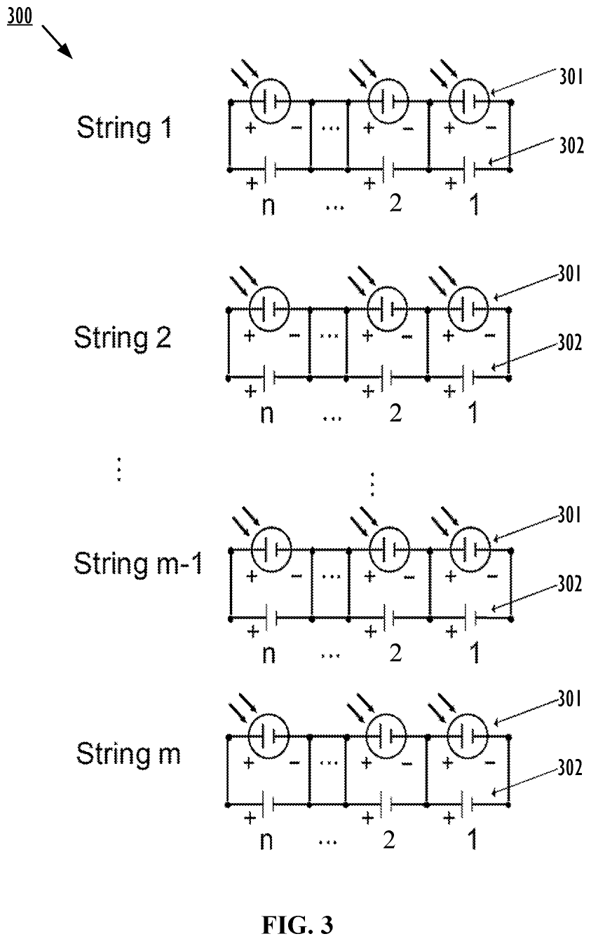

The present disclosure provides a rotationally symmetric array of PV cells, in which PV cells connected in series as strings, as illustrated in the example of FIG. 2. Each PV cell in the array may have an energy storage element connected in parallel to the PV cell, as illustrated in the example of FIG. 3.

FIG. 2 is a schematic layout of an exemplary PV receiver for free-space optical power beaming according to described examples. The PV receiver 201 includes a first string of PV cells 202, a second string of PV cells 203, and a third string of PV cells 204. In the examples of FIG. 2, although 3 strings are shown, a number of strings can be chosen as other suitable values. A number “m” of the strings may be chosen according to various application scenarios. The number m of the strings may be any suitable positive integer, such as 1, 2, 3, 4, 5, 6, 7, 8, 9, etc.

The PV receiver 201 may be under illumination of a radially symmetric optical beam (e.g., laser beam), having a Gaussian distribution or any other radially symmetric distribution. The laser beam may illuminate each of PV cells of a string uniformly, such as the “n” PV cells in the first string of PV cells 202. Accordingly, the PV cells (e.g., 202, 203, or 204) in a same string may receive same or approximately same amount of illumination power in response to the PV receiver 201 receiving the optical beam, and the PV cells may be current matched in the same string. In some examples, by electrically connecting the second string of PV cells 203 in parallel to the first string of PV cells 202, an additional power is provided with reduced loss due to non-uniform illumination. By electrically connecting the “m” strings in parallel, the full power of the PV receiver 201 may be increased with reduced losses due to not-uniform illumination.

In some examples, each string in the PV receiver 201 has an equal number of PV cells. In the examples of FIG. 2, a number “n” of the PV cells of the first string of PV cells 202 is 8, the number of the PV cells of the second string of PV cells 203 is 8, and the number of the PV cells of the third string of PV cells 204 is 8. In other examples, certain strings in the PV receiver 201 have different numbers of PV cells; the number “n” of the PV cells of the first string of PV cells 202 is a positive integer such as 8, but the number of the PV cells of the second string of PV cells 203 may be a different positive integer, such as 4. In some examples, the number of the PV cells of an individual string of PV cells may be a positive integer greater than 1. The number of the PV cells of each string of PV cells may be chosen according to various application scenarios.

Referring to FIG. 2, individual strings in the PV receiver 201 each has rotational symmetry around a center 205; and the first string of PV cells 202, the second string of PV cells 203, and the third string of PV cells 204 have the same center 205. In some examples, the rotational symmetry of each string in the PV receiver 201 has the same order. In the examples of FIG. 2, the first string of PV cells 202 has rotational symmetry with order of 8 around the center 205; the second string of PV cells 203 has rotational symmetry with order of 8 around the center 205; and the third string of PV cells 204 has rotational symmetry with order of 8 around the center 205. In other examples, some or all strings in the PV receiver 201 may have rotational symmetry with different orders. For example, the order of rotational symmetry of the first string of PV cells may be 8, but the order of rotational symmetry of the second string of PV cells may be 4. In some examples, the order of rotational symmetry of an individual string of PV cells may be a positive integer greater than 1. The order of rotational symmetry of each string of PV cells may be chosen according to various application scenarios.

In another embodiment, the strings in the PV receiver 201 may be arranged without rotational symmetry. In some examples, individual strings in the PV receiver 201 each may have no rotational symmetry, but PV cells in each individual strings may still receive the same or approximately same amount of illumination power.

In some examples, the strings in the PV receiver 201 may be wired or connected in parallel. In other examples, some or all of the strings in the PV receiver 201 may be wired or connected in series. In another examples, some or all of the strings in the PV receiver 201 may be wired or connected in combination of series and parallel. The wiring or connection of the photovoltaic cells may be chosen according to required power output, current and voltage for various application scenarios.

The present disclosure provides a PV receiver having an array of PV cells, which includes strings of PV cells series connected in each individual strings, where each individual string has a rotationally symmetric pattern. The PV receiver may have m strings (m≥1), where each string may have at least two PV cells, and the at least two PV cells may be connected in series in the string. The m strings may be connected in parallel.

In some examples, the strings are arranged to have a circular or annular shape or approximately a circular or annular shape, and positioned so that strings are roughly symmetrically illuminated with a Gaussian profile circular beam. For example, a center of Gaussian profile circular beam is pointed at a center of the strings (e.g., center 205 in FIG. 2). The PV receiver consistent with the present disclosure, such as the PV receiver 201 of FIG. 2, may mitigate the effects of the inherently non-uniform Gaussian beam profile with a symmetrical arrangement of strings and by connecting the strings in parallel. Individual PV cells within each of the strings may be in a rotational symmetric arrangement (e.g., a circular symmetric arrangement); and, accordingly, may be current matched under Gaussian illumination.

In some examples, a cross-section of a photovoltaic cell (e.g., 202, 203, 204) of the strings of photovoltaic cells has a triangle shape, a square shape, or a trapezium shape. The shape of the photovoltaic cells may be chosen according to various application scenarios.

In some examples, a distance D3 between the center 205 and a center 3C of a PV cell 203 of the second string of PV cells 203 is larger than a distance D2 between the center 205 and a center 2C of a PV cell 202 of the first string of PV cells 202; and an area (e.g., size) of a PV cell 203 of the second string of PV cells 203 is larger than an area of a PV cell 202 of the first string of PV cells 202. Accordingly, under Gaussian illumination, the PV cell 203 may be exposed to or receive smaller power density than the PV cell 202; and with a larger area, the PV cell 203 may receive the same or approximately same amount of illumination power as the PV cell 202, such that the PV cell 203 is current matched with the PV cell 202.

Similarly, in some examples, a distance D4 between the center 205 and a center 4C of a PV cell 204 of the third string of PV cells 204 is larger than a distance D3 between the center 205 and a center 3C of a PV cell 203 of the second string of PV cells 203; and an area (e.g., size) of a PV cell 204 of the third string of PV cells 204 is larger than an area of a PV cell 203 of the second string of PV cells 203. Under Gaussian illumination, the PV cell 204 may receive smaller power density than the PV cell 203. With a larger area, the PV cell 204 may receive the same or approximately same amount of illumination power as the PV cell 203, such that the PV cell 204 may be current matched with the PV cell 203.

In some examples, individual PV cells 202, 203, 204 may be sized and shaped to receive the same or approximately same amount of illumination power, such that individual PV cells 202, 203, 204 may be current matched with each another; and the first string of PV cells 202 may be connected in series to the second string of PV cells 203, and may be connected in series to the third string of PV cells 204. As the individual PV cells 202, 203, 204 receive the same or approximately same amount of illumination power, the output power of the PV receiver may be increased. In some examples, individual PV cells 202, 203, 204 may be defined by laser cutting or mechanical cutting from a solar cell.

As further illustrated, each of the cells in the first string of PV cells 202 have two sides or edges that each touch a neighboring cell along an adjoining edge, such that all of the cells in the first string 202 are contiguous with one another. Each of the sides can be linear, and a third outer edge is also linear, so that each cell 202 has a substantially triangular shape and are equal in size and together form an octagon.

The second string of cells 203 are concentrically arranged about the first string of cells 202. The second string of cells 203 each have two sides or edges that each touch a neighboring cell along an adjoining edge, such that all of the cells in the second string 203 are contiguous with one another. In addition, each of the cells 203 have an inner edge and an outer edge, which can each be linear, and the inner edge of the second cells 203 can touch the outer edge of the first cells 202. Each cell 203 can have a substantially trapezoid or parallelogram shape and are equal in size and together form an octagon.

The third string of cells 204 are concentrically arranged about the first string of cells 202 and the second string of cells 203. The third string of cells 204 each have two sides or edges that each touch a neighboring cell along an adjoining edge, such that all of the cells in the third string 204 are contiguous with one another. In addition, each of the cells 204 have an inner edge and an outer edge, which can each be linear, and the inner edge of the second cells 204 can touch the outer edge of the second cells 203. Each cell 204 can have a substantially trapezoid or parallelogram shape and are equal in size and together form an octagon.

In one embodiment, the cells of each string of cells 202, 203, 204 can be formed distinct from one another. In another embodiment, one or more or all of the first cells 202 can be integrally formed with one another; one or more or all of the second cells 203 can be integrally formed with one another; and one or more or all of the third cells 204 can be integrally formed with one another. In addition, the first cells 202, second cells 204 and third cells 205 can be separately formed, or two or more of the cells 202, 204, 205 can be integrally formed.

In some examples, each cell of the first string all receives a similar light intensity and those cells are wired in series, and accordingly, those cell's current output is matched and no losses are expected. In a PV receiver consistent with the present disclosure, such as the PV receiver 201, each string can generate power without losses due to current mismatch under non-uniform illumination. In addition, each string may operate independently over other strings and each string may contribute to the total power generation. In certain examples, each string is equipped with its own connector and power management system.

FIG. 3 illustrates a diagram of another example PV receiver according to described examples. The PV receiver 300 includes m strings of PV cells 301. Each string includes n PV cells 301 coupled in series, and each of the n cells 301 has an energy storage element 302 connected in parallel with the cell 301. Under temporally non-uniform illumination, the energy storage element 302 may provide electrical current to the circuit in response to a PV cell 301 in a string instantaneously receiving less light than other PV cells 301 in the string.

The energy storage elements 302 may act as energy buffers that store energy so that intensity scintillations created by a laser propagating through a turbulent atmosphere can effectively be smoothed out over time. For example, in response to a PV cell 301 receiving excess energy, in a given time period, the excess energy may be stored in the storage element 302 by the PV cell 301 of the PV receiver 300. In response to a PV cell 301 is under-illuminated during another time period, e.g., a subsequent instant in time, the energy storage element 302 may deliver energy to the string. In some examples, the energy storage element 302 may include a capacitor, a super-capacitor, an electro-chemical battery cell, and/or any other suitable energy storage device. In certain examples, the m strings are connected in parallel. In other examples, some or all of the m strings are connected in series.

The energy storage elements 302 may include capacitors, electro-chemical battery cells, and/or any other suitable energy storage elements. The energy storage elements 302 may be chosen according to various application scenarios and factors, such as laser energy density, the frequency spectrum of the laser scintillation, and/or the current-voltage characteristic of individual PV cells.

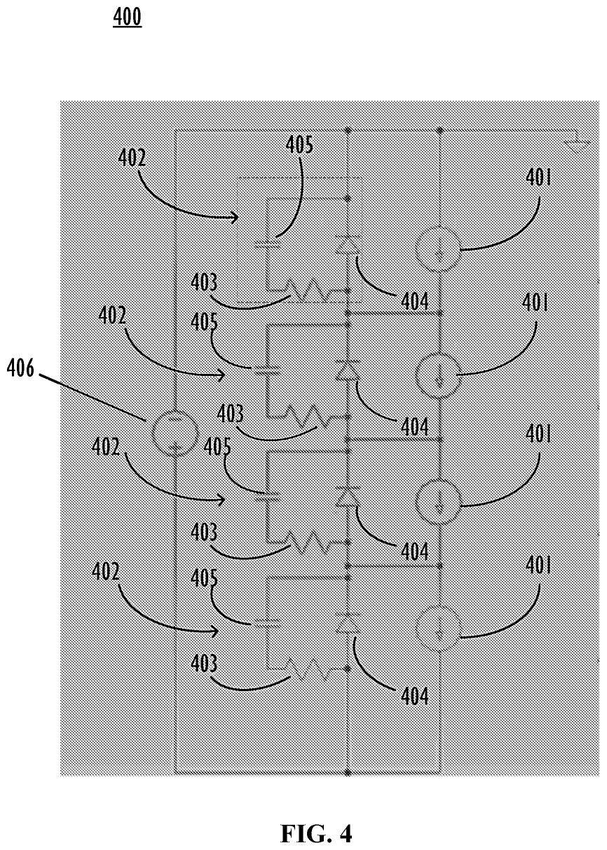

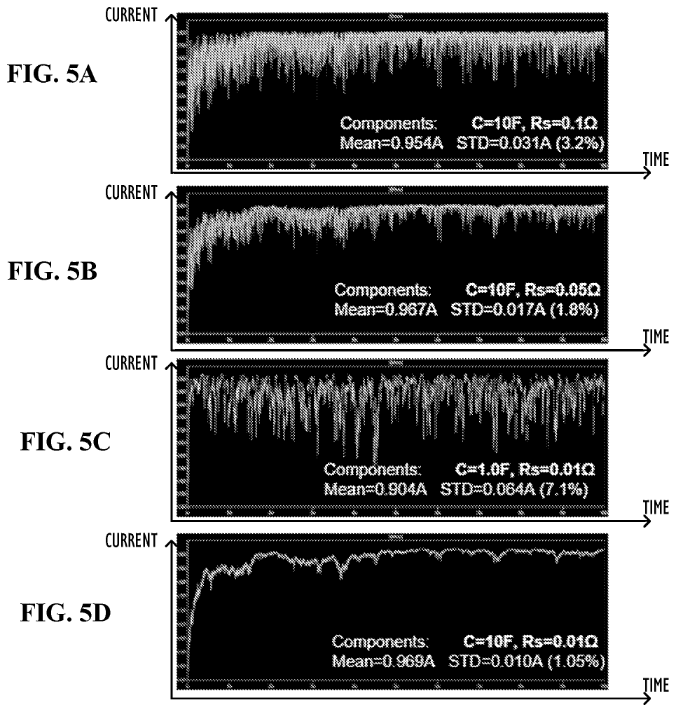

FIG. 4 illustrates a circuit diagram of another example PV receiver according to described examples; and FIGS. 5A to 5D illustrate example current-versus-time graphs for the example PV receiver in FIG. 4 according to described examples. Referring to FIG. 4, the PV receiver 400 includes a string of PV cells 401, and the string of PV cells 401 are coupled in series. The PV receiver 400 further includes storage elements 402 each coupled in parallel to a PV cell 401. The storage element 402 includes a resistor 403, a diode 404, and a capacitor 405, where the resistor 403 is coupled in series to the capacitor 405, and the diode 404 is coupled in parallel to the resistor 403 and the capacitor 405. The arrow shown in the PV cell 401 indicates the current generated in each PV cell 401. The capacitor 405 may be, for example, a super capacitor. The PV receiver 400 may further include a voltage source 406 that provides a bias voltage to the string of PV cells 401 and which may be arranged to operate as a maximum power point tracker. The capacitor (C) 405 in series with the resistor (R) 403 forms a RC charging circuit connected across the PV cell 401 via the voltage source 406 as a switch. At time zero, when the switch is first closed, the capacitor 405 gradually charges up through the resistor 403, e.g., until the voltage across it reaches the supply voltage of an external battery (not shown in FIG. 4). In some examples, the capacitor 405 may be used as energy storage and may be supplements to the external battery. The diode 404 ensures that the capacitor 405 rapidly discharges into the positive rail when power is switched off, enabling the proper reset taking place on power-up.

FIGS. 5A to 5D illustrate the output current of the PV receiver 400 with various example component configurations according to described examples. FIGS. 5A to 5D correspond to example component configurations with the resistances “Rs” of the resistors 403 equal to 0.1 ohms (Ω) and capacitances “C” of capacitors 405 equal to 10 farads (F), with the resistances “Rs” of the resistors 403 equal to 0.05 ohms and capacitances “C” of capacitors 405 equal to 10 farads, with the resistances “Rs” of the resistors 403 equal to 0.01 ohms and capacitances “C” of capacitors 405 equal to 1.0 farads, and with the resistances “Rs” of the resistors 403 equal to 0.01 ohms and capacitances “C” of capacitors 405 equal to 10 farads, respectively. FIGS. 5A to 5D correspond to the scenarios that the voltage source 405 provides the string of PV cells 401 with a direct-current (DC) voltage of approximately 2.9 volts, which simulates the string being biased near, e.g., a maximum power point.

FIGS. 5A to 5D show example graphs of current vs. time, for a pseudo-random photocurrent with a noise spectrum similar to that may be found in measurements of current fluctuations caused by illumination in high atmospheric turbulence. FIGS. 5A to 5D show a mean current out of the PV receiver 400 equal to 0.954 amperes (A) and a standard deviation (STD) of 0.031 amperes and 3.2%, a mean current out of the PV receiver 400 equal to 0.967 amperes (A) and a standard deviation (STD) of 0.017 amperes and 1.8%, a mean current out of the PV receiver 400 equal to 0.904 amperes (A) and a standard deviation (STD) of 0.064 amperes and 7.1%, and a mean current out of the PV receiver 400 equal to 0.969 amperes (A) and a standard deviation (STD) of 0.010 amperes and 1.05%, respectively. With the resistances “Rs” of the resistors 403 equal to 0.01 ohms and capacitances “C” of capacitors 405 equal to 10 farads, FIG. 5D shows a higher average current out of the PV receiver 400 and a lower standard deviation (STD) than FIGS. 4A to 4C.

A material of a PV cell consistent with the present disclosure, such as above-described PV cell 201, 300, 400, may include, for example, at least one of semiconductors such as amorphous silicon, multi (poly-) crystalline silicon, mono-crystalline silicon, cadmium telluride (CdTe), CIGS (CuIn_{1-y}Ga_{y}Se₂), CZTSSe (Cu₂ZnSnS_{4-y}Se_{y}), CZTS (Cu₂ZnSnS₄), III-V compounds semiconductors (e.g. GaAs, InP), organic, dye-sensitized, or perovskite materials. The type of PV cell may include, for example, front-junction front contact cell and/or rear-junction rear contact cell, and may be chosen according to various application scenarios. Various shapes may be chosen for the rotationally symmetric string according to application scenarios.

In some examples, another PV receiver may include vertical multi-junction (VMJ) cells, also referred to as “edge-illumination solar cells,” and/or a monolithically integrated module (MIM), in which the solar cells are grown on a semi-insulating substrate and small area strings are defined using photolithography and etching.

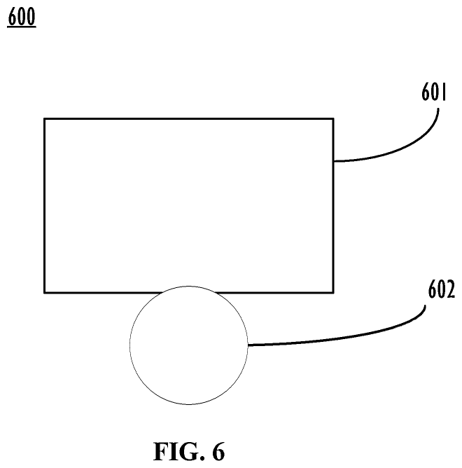

FIG. 6 illustrates a block diagram of an exemplary PV-receiver device 600 according to described examples. The PV-receiver device 600 includes a body 601 and a PV receiver 602. The PV receiver 602 is coupled or attached to the body 601. The PV receiver 602 may be a PV receiver consistent with the present disclosure, such as any one of the above-described PV receivers 201, 300, 400. In some examples, the PV receiver 602 may be the above-described PV receiver 201, and have an octagon shape. In other examples, the PV receiver 602 may have an circular shape. Various shapes may be chosen for the PV receiver 602 according to application scenarios. The body 601 may include, for example, unmanned systems, such as unmanned aerial vehicles (UAVs), unmanned surface vehicles (USVs), unmanned ground vehicles (UGVs) and unmanned undersea vehicles (UUVs), sensor networks on the ground, and/or satellites. The PV receiver 602 may receive power of an optical beam from ground and provide power to the body 601.

The present disclosure provides a PV receiver that includes one or more strings of PV cells. Individual strings may have rotational symmetry with respect to a center, and may include PV cells in series with one another in the individual string. Accordingly, individual PV cells in the same string may be exposed to or receive the same or approximately the same amount of illumination power, and are current matched. In some examples, approximately same amount of illumination power for individual PV cells may indicate that the differences in the amount of illumination power for individual PV cells are within 5%. Accordingly, power output of the PV receiver may be increased. Further, individual PV cells in a string may each have an energy storage element connected in parallel with the PV cell. Under temporally non-uniform illumination, in response to that a PV cell in a string receives excess energy, in a given time slice, the excess energy may be stored in the energy storage element; and in response to that a PV cell receives less power than other PV cells in the string, in a given time slice, the energy storage element may provide electrical current to the circuit. Accordingly, stability of power output of the PV receiver may be improved.

It is noted that the cell configuration of FIG. 2 can be utilized with the circuit of FIG. 3 and/or FIG. 4. However, the structure of FIG. 2 can be utilized with other circuits, and the circuit of FIGS. 3, 4 can be utilized with other cell configurations.

It is noted that the drawings may illustrate, and the description and claims may use geometric or relational terms, such as side, edge, inner, outer, linear, parallelogram, trapezoid, triangular, rotational, concentrically, etc. These terms are not intended to limit the disclosure and, in general, are used for convenience to facilitate the description based on the examples shown in the figures. In addition, the geometric or relational terms may not be exact. For instance, walls may not be exactly perpendicular or parallel to one another because of, for example, roughness of surfaces, tolerances allowed in manufacturing, etc., but may still be considered to be perpendicular or parallel.

Within this specification, the various sizes, shapes and dimensions are approximate and exemplary to illustrate the scope of the invention and are not limiting. The sizes and the terms “substantially” and “approximately” mean plus or minus 15-00%, or in other embodiments plus or minus 10%, and in other embodiments plus or minus 5%, and plus or minus 1-2%. In addition, while specific dimensions, sizes and shapes may be provided in certain embodiments of the invention, those are simply to illustrate the scope of the invention and are not limiting. Thus, other dimensions, sizes and/or shapes can be utilized without departing from the spirit and scope of the invention.

It will be apparent to those skilled in the art having the benefit of the teachings presented in the foregoing descriptions and the associated drawings that modifications, combinations, sub-combinations, and variations can be made without departing from the spirit or scope of this disclosure. Likewise, the various examples described may be used individually or in combination with other examples. Those skilled in the art will appreciate various combinations of examples not specifically described or illustrated herein that are still within the scope of this disclosure. In this respect, it is to be understood that the disclosure is not limited to the specific examples set forth and the examples of the disclosure are intended to be illustrative, not limiting.

1. A photovoltaic receiver, comprising:
a plurality of photovoltaic cells that are coupled to one another in series, the plurality of photovoltaic cells arranged to have rotational symmetry with respect to a reference point; and an energy storage element for a photovoltaic cell of the plurality of photovoltaic cells and being coupled to one of the plurality of photovoltaic cells in parallel.

2. The photovoltaic receiver of claim 1, wherein the reference point is a center of the plurality of photovoltaic cells.

3. The photovoltaic receiver of claim 1, wherein a cross-section of one of the plurality of photovoltaic cells has a triangle shape, a square shape, or a trapezium shape.

4. The photovoltaic receiver of claim 1,
wherein an order of the rotational symmetry is an integer equal to or greater than 2.

5. The photovoltaic receiver of claim 1,
wherein the energy storage element includes at least one of the following: a capacitor, a super-capacitor, an electro chemical battery cell.

6. The photovoltaic receiver of claim 1, wherein:
the plurality of photovoltaic cells is a first string of photovoltaic cells;
the photovoltaic receiver further comprising:
a second string of photovoltaic cells that include at least two photovoltaic cells, wherein the second string of photovoltaic cells have rotational symmetry with respect to the same reference point as the first string of photovoltaic cells.

7. The photovoltaic receiver of claim 6, wherein the second string of photovoltaic cells are coupled in parallel to the first string of photovoltaic cells.

8. The photovoltaic receiver of claim 6, wherein an order of the rotational symmetry of the first string of photovoltaic cells is equal to an order of the rotational symmetry of the second string of photovoltaic cells.

9. The photovoltaic receiver of claim 6, wherein an order of the rotational symmetry of the first string of photovoltaic cells is greater than an order of the rotational symmetry of the second string of photovoltaic cells.

10. The photovoltaic receiver of claim 6, wherein:
a distance between the reference point and a photovoltaic cell of the second string of photovoltaic cells is larger than a distance between the reference point and a photovoltaic cell of the first string of photovoltaic cells; and
the photovoltaic cell of the second string of photovoltaic cells has a larger size than the photovoltaic cell of the first string of photovoltaic cells.

11. The photovoltaic receiver of claim 6, wherein:
a cross-section of a photovoltaic cell of the first string of photovoltaic cells has a triangle shape; and
a cross-section of a photovoltaic cell of the second string of photovoltaic cells has a trapezium shape.

12. The photovoltaic receiver of claim 1, wherein a material of a photovoltaic cell of the plurality of photovoltaic cells includes at least one of amorphous silicon, poly-crystalline silicon, mono-crystalline silicon, cadmium telluride, copper-indium-gallium-selenide (CIGS), Cu—Zn—Sn—S—Se, Cu—Zn—Sn—S, III-V compounds semiconductor, organic material, dye-sensitized materials, or perovskite material.

13. The photovoltaic receiver of claim 1, wherein:
in response to a first one of the plurality of photovoltaic cells receiving excess energy beyond an average energy received by individual photovoltaic cells of the plurality of photovoltaic cells in a time slice, the first photovoltaic cell stores excess energy to the energy storage element; and
in response to the first photovoltaic cell receiving energy less than the average energy received by individual photovoltaic cells of the plurality of photovoltaic cells in the time slice, the energy storage element provides energy to the first photovoltaic cell.

14. The photovoltaic receiver of claim 6, wherein the individual photovoltaic cells of the first string of photovoltaic cells receive same or approximately same first amount of illumination power in response to the photovoltaic receiver receiving an optical beam, and the individual photovoltaic cells of the second string of photovoltaic cells receive same or approximately same second amount of illumination power in response to the photovoltaic receiver receiving the optical beam, the first amount being different than the second amount.

15. A photovoltaic receiver, comprising:
a string of photovoltaic cells that include at least two photovoltaic cells, wherein: the string of photovoltaic cells are coupled to one another in series;
the string of photovoltaic cells have rotational symmetry with respect to a reference point; and
individual photovoltaic cells of the string of photovoltaic cells receive same or approximately same amount of illumination power in response to the photovoltaic receiver receiving an optical beam.

16. The photovoltaic receiver of claim 15, wherein currents corresponding to the individual photovoltaic cells of the string of photovoltaic cells are the same or approximately the same.

17. The photovoltaic receiver of claim 15, further comprising:
an energy storage element for a first photovoltaic cell of the string of photovoltaic cells and being coupled to the first photovoltaic cell in parallel.

18. The photovoltaic receiver of claim 15, wherein:
in response to a first photovoltaic cell of the string of photovoltaic cells receiving excess energy beyond an average energy received by individual photovoltaic cells of the string of photovoltaic cells in a time slice, the first photovoltaic cell stores excess energy to the energy storage element; and
in response to the first photovoltaic cell receiving energy less than the average energy received by individual photovoltaic cells of the string of photovoltaic cells in the time slice, the energy storage element provides energy to the first photovoltaic cell.

19. The photovoltaic receiver of claim 15, further comprising:
additional energy storage elements, wherein:
the energy storage element and additional energy storage elements each is parallel to and coupled to a photovoltaic cell of the string of photovoltaic cells.

20. A device, comprising:
a body, and
a photovoltaic receiver coupled or attached to the body, the photovoltaic receiver including:
a string of photovoltaic cells that include at least two photovoltaic cells, wherein:
the string of photovoltaic cells are coupled to one another in series; and the string of photovoltaic cells have rotational symmetry with respect to a reference point.

21. The device of claim 20, wherein the body includes at least one of an unmanned system, a sensor network, or a satellite.
